(19) United States
(12) Patent Application Publication
(10) Pub. No.: US 2013/0098443 A1
(43) Pub. Date: Apr. 25, 2013

(54) PLATE MEMBER, LIGHT CONDENSING SOLAR BATTERY, AND SOLAR ENERGY GENERATING WINDOW

(71) Applicant: Kyohko Azumada, Osaka-shi (JP)

(72) Inventor: Kyohko Azumada, Osaka-shi (JP)

(73) Assignee: SHARP KABUSHIKI KAISHA, Osaka-shi, Osaka (JP)

(21) Appl. No.: 13/806,329

(22) PCT Filed: Jun. 14, 2011
(86) PCT No.: PCT/JP2011/063600

§ 371 Date: Dec. 21, 2012

(30) Foreign Application Priority Data
Jun. 21, 2010 (JP) 2010-140717

(51) Int. Cl. H01L 31/055; G02B 19/00

(52) U.S. Cl. CPC H01L 31/055; G02B 19/0042
USPC 136/257; 250/458.1

(57) ABSTRACT

A plate member of the present invention has an entrance surface (1); an end surface (2) from which a part of entered light, which has entered the entrance surface (1) and has been guided to the end surface (2), exits; and an exit surface (3) from which at least part of rest of the entered light exits. The plate member includes a fluorescent concentrating plate (10) containing fluorescent molecules and a dielectric multilayer mirror (11). The dielectric multilayer mirror (11) (i) reflects light having a complementary color of a color of light generated by the fluorescent molecules or (ii) causes light having the complementary color to pass through. The plate member is configured by stacking the fluorescent concentrating plate (10) and the dielectric multilayer mirror (11).

### DESCRIPTION

1. Technical Field

The present invention relates to a plate member, a concentrating solar cell device, and a solar power generating window. The present invention relates to a plate member, a concentrating solar cell device including the plate member, and a solar power generating window, each of which can be employed as, for example, a hardly colored windowpane.

2. Background Art

In recent years, attentions are being given to the solar cell technology as a technique to solve an energy problem or a global warming problem. Development of a concentrating solar cell is being demanded because of high conversion efficiency from sunlight to electricity and of further resource saving, as compared with widely used conventional silicon solar cells. The concentrating solar cell can include, as a light concentrating member, a lens, a reflecting mirror, or a light concentrating plate containing organic dye molecules (hereinafter, referred to also as “fluorescent molecules”). The following exemplifies conventional techniques employing a light concentrating plate containing fluorescent molecules.

Patent Literature 1 discloses a window surface solar cell power generation system in which a window frame is formed by adhering a solar cell to a lateral face, which is perpendicular to a daylight surface, of a transparent light absorbing/emitting plate in which fluorescent substances are dispersed.

Patent Literature 2 discloses a solar energy collecting window made up of a fluorescent concentrating plate, a solar cell, and a frame member. The fluorescent concentrating plate is produced by a liquid phase deposition. The solar cell is provided at a part onto which sunbeams are converged by the fluorescent concentrating plate.

### CITATION LIST

### Patent Literatures

[Patent Literature 1]

Japanese Unexamined Utility Model Application Publication Jitsukaisho No. 61-136559 (Publication date: Aug. 25, 1986)
[Patent Literature 2]

Japanese Patent Application Publication Tokukaihei No. 3-273686 A (Publication date: Dec. 4, 1991)

### SUMMARY OF INVENTION

### Technical Problem

In a case where a light concentrating plate containing fluorescent molecules is employed out of concentrating solar cells, such a light concentrating plate can be provided in a building as a solar power generating window because the light concentrating plate has a light-transmitting property. According to the solar power generating window, the light concentrating plate containing the fluorescent molecules serves as a windowpane.

The solar power generating window has a structure which is formed by, for example, (i) depositing fluorescent molecules, which are excited by light having a particular wavelength, on a surface of a transparent substrate such as a glass and (ii) providing a solar cell on an end surface of the transparent substrate. The fluorescent molecules generate fluorescence in response to excitation by entered light. The fluorescence thus generated (i) is guided to the end surface of the transparent substrate while being subjected to total reflection and the like and then (ii) enters the solar cell as high density light. Since the fluorescent molecules are contained, the light concentrating plate is in a color specific to the fluorescent molecules, that is, a color such as red, green, or blue derived from the fluorescent molecules.

FIG. 15 is a view schematically illustrating a configuration of a conventional solar power generating window 700. The solar power generating window 700 includes a fluorescent concentrating plate 710, a solar cell 712, and an aluminum frame 713. The solar cell 712 is provided on an end surface 702 of the fluorescent concentrating plate 710.

The following description will discuss a power generation principle of the solar power generating window 700, with reference to FIG. 16. FIG. 16 is a schematic view for illustrating how light is guided in the fluorescent concentrating plate 710 of the solar power generating window 700. Fluorescent molecules contained in the fluorescent concentrating plate 710 generate fluorescence 770 in response to excitation by incoming light 14. The fluorescence 770 is guided inside the fluorescent concentrating plate 710, while being subjected to total reflection as indicated by a light path 771, toward the end surface 702 of the fluorescent concentrating plate 710. Guided light enters the solar cell 712 provided adjacently on the end surface 702.

FIG. 17 illustrates the solar power generating window 700 viewed from an outdoor side. The solar power generating window 700 is in a color derived from the fluorescent molecules.

In a case where a solar power generating window is used as a windowpane, it is demanded that the solar power generating window is not colored. Therefore, in a case where the light concentrating plate which is colored as above described is employed as a windowpane, a view from inside a building is spoiled and also the building is disfigured. Moreover, a colored fluorescent concentrating plate limits its application range as a windowpane, and therefore interferes with its practical application.

In view of the circumstances, an object of the present invention is to provide a plate member which is suitably applicable to a windowpane while suppressing coloring, without disfiguring a building and/or spoiling a view from inside the building. A further object of the present invention is to provide a concentrating solar cell device including the plate member and a solar power generating window system including the plate member.

### Solution to Problem

In order to attain the object, a plate member of the present invention has a light entrance surface; a first exit surface from which first light exits, the first light (i) being a part of entered light which has entered the light entrance surface and (ii) having been guided toward the first exit surface; and a second exit surface from which second light exits, the second light being at least part of rest of the entered light, the plate member including: a fluorescent layer containing fluorescent molecules; and an optical layer, the optical layer (i) reflecting light having a complementary color of a color of light generated by the fluorescent molecules or (ii) causing the light, having the complementary color of the color of the light generated by the fluorescent molecules, to pass through, and the fluorescent layer and the optical layer being stacked.

According to the configuration, sunlight enters the fluorescent layer via the light entrance surface, and a part of entered light excites the fluorescent molecules, which are contained in the fluorescent layer, so that fluorescence is generated. Generated fluorescence is guided to the first exit surface while being subjected to total reflection in the fluorescent layer. Moreover, at least part of rest of the entered light exits from the second exit surface.

The fluorescent layer and the optical layer are stacked. The optical layer (i) reflects light having a complementary color of a color of light generated by the fluorescent molecules and (ii) causes light having the color of light generated by the fluorescent molecules to pass through. Alternatively, the optical layer (i) causes the light, having the complementary color of the color of the light generated by the fluorescent molecules, to pass through and (ii) reflects the light having the color of the light generated by the fluorescent molecules. That is, the optical layer can selectively transmit or reflect any one of (i) the light having the color of the light generated by the fluorescent molecules and (ii) the light having the complementary color of the color of the light generated by the fluorescent molecules.

In a case where the plate member is viewed by a viewer who is outside a building (outdoor) or inside the building (indoor), it is possible to suppress coloring of the plate member because a color of the fluorescent concentrating plate is mixed with a color of light which has been reflected from or has passed through the dielectric multilayer mirror. With the configuration, the plate member of the present invention can be suitably employed as, for example, a windowpane without disfiguring the building or spoiling a view from the indoor side.

A concentrating solar cell device of the present invention includes: the above described plate member and a solar cell, the first exit surface facing the solar cell so that light, which has exited from the first exit surface, enters the solar cell.

According to the configuration, entered sunlight excites the fluorescent molecules, which are contained in the fluorescent layer of the plate member, so that fluorescence is generated. The fluorescence is guided to the first exit surface while being subjected to total reflection and the like in the fluorescent layer, and then enters the solar cell. This makes it possible to provide the concentrating solar cell device which (i) has the plate member that is hardly colored and (ii) is capable of generating electric power by the solar cell.

A solar power generating window of the present invention includes the above described concentrating solar cell device.

According to the configuration, the plate member which is hardly colored is provided. Therefore, the solar power generating window can be suitably employed as a window of a building, without disfiguring the building and/or spoiling a view from an indoor side.

### Advantageous Effects of Invention

The plate member of the present invention has a light entrance surface; a first exit surface from which first light exits, the first light (i) being a part of entered light which has entered the light entrance surface and (ii) having been guided toward the first exit surface; and a second exit surface from which second light exits, the second light being at least part of rest of the entered light, the plate member including: a fluorescent layer containing fluorescent molecules; and an optical layer, the optical layer (i) reflecting light having a complementary color of a color of light generated by the fluorescent molecules or (ii) causing the light, having the complementary color of the color of the light generated by the fluorescent molecules, to pass through, and the fluorescent layer and the optical layer being stacked. This allows the plate member to be suitably employed as a windowpane, without (i) disfiguring a building and (ii) spoiling a view from inside of the building.

Moreover, each of the concentrating solar cell and the solar power generating window includes the plate member which is hardly colored and is to serve as a windowpane. Therefore, in a case where the concentrating solar cell or the solar power generating window is employed as a windowpane, it is possible to prevent spoiling of (i) an appearance of a building and (ii) a view from inside of the building.

### BRIEF DESCRIPTION OF DRAWINGS

FIG. 1 is a schematic view illustrating a configuration of a solar power generating window in accordance with an embodiment of the present invention.

FIG. 2 is a schematic view for illustrating how light is guided in a fluorescent concentrating plate of a solar power generating window in accordance with an embodiment of the present invention.

FIG. 3 is a schematic view for illustrating a principle of how coloring of a solar power generating window in accordance with an embodiment of the present invention is suppressed.

FIG. 4 is a view illustrating a solar power generating window which is viewed from an outdoor side in accordance with an embodiment of the present invention.

FIG. 5 is a schematic view illustrating a configuration of a solar power generating window in accordance with an embodiment of the present invention.

FIG. 6 is a schematic view for illustrating a principle of how coloring of a solar power generating window in accordance with an embodiment of the present invention is suppressed.

FIG. 7 is a schematic view illustrating a configuration of a solar power generating window in accordance with an embodiment of the present invention.

FIG. 8 is a schematic view for illustrating a principle of how coloring of a solar power generating window in accordance with an embodiment of the present invention is suppressed.

FIG. 9 is a schematic view illustrating a configuration of a solar power generating window in accordance with an embodiment of the present invention.

FIG. 10 is a schematic view for illustrating a principle of how coloring of a solar power generating window in accordance with an embodiment of the present invention is suppressed.

FIG. 11 is a schematic view illustrating a configuration of a solar power generating window in accordance with an embodiment of the present invention.

FIG. 12 is a schematic view for illustrating a principle of how coloring of a solar power generating window in accordance with an embodiment of the present invention is suppressed.

FIG. 13 is a schematic view illustrating a configuration of a solar power generating window in accordance with an embodiment of the present invention.

FIG. 14 is a schematic view for illustrating a principle of how coloring of a solar power generating window in accordance with an embodiment of the present invention is suppressed.

FIG. 15 is a schematic view illustrating a configuration of a conventional solar power generating window.

FIG. 16 is a schematic view for illustrating a principle of how electric power is generated by a conventional solar power generating window.

FIG. 17 is a view illustrating a conventional solar power generating window which is viewed from an outdoor side.

### DESCRIPTION OF EMBODIMENTS

### Embodiment 1

(Configuration of solar power generating window 100) The following description will discuss an embodiment of the present invention, with reference to FIG. 1. FIG. 1 is a schematic view illustrating a configuration of a solar power generating window 100 in accordance with Embodiment 1.

The solar power generating window 100 includes a plate member 30, a solar cell 12, and an aluminum frame 13 (see FIG. 1). The plate member 30 includes a fluorescent concentrating plate 10 (fluorescent layer, first substrate) and a dielectric multilayer mirror 11 (optical layer, second substrate).

(Fluorescent Concentrating Plate 10)

The fluorescent concentrating plate 10 has an entrance surface 1, an end surface 2 (first exit surface), and an exit surface 3 (second exit surface). The fluorescent concentrating plate 10 contains fluorescent molecules (not illustrated). Examples of a substrate of the fluorescent concentrating plate 10 encompass a substrate such as a glass substrate. Note, however, that the substrate constituting the fluorescent concentrating plate 10 is not limited to this, provided that the substrate has a light-transmitting property. A layer containing the fluorescent molecules is provided in the substrate (first substrate) or on a surface of the substrate. The entrance surface 1 and the exit surface 3 serve as a front surface and a back surface, respectively, of the fluorescent concentrating plate 10.

The fluorescent molecules contained in the fluorescent concentrating plate 10 are not limited to a material having specific type, excitation light wavelength, and emission color, provided that the fluorescent molecules generate fluorescence in response to excitation by entered light.

According to Embodiment 1, the fluorescent concentrating plate 10 contains fluorescent molecules which generate green fluorescence in response to excitation by purple light. Examples of such fluorescent molecules encompass Lumogen F Yellow 083 (manufactured by BASF). Note, however, that the fluorescent molecules are not limited to this.

(Dielectric Multilayer Mirror 11)

The dielectric multilayer mirror 11 and the fluorescent concentrating plate 10 are stacked as follows so as to provide the plate member 30. Namely, the dielectric multilayer mirror 11 is stacked on the fluorescent concentrating plate 10, via an exit surface 3 of the fluorescent concentrating plate 10. The solar power generating window 100 is provided so that (i) the fluorescent concentrating plate 10 is located on an outdoor side which incoming light 14 enters and (ii) the dielectric multilayer mirror 11 is located on an indoor side.

The dielectric multilayer mirror 11 can be prepared by alternating, on a substrate, layers of (i) a first dielectric material having a high refractive index and (ii) a second dielectric material having a low refractive index. For example, the dielectric multilayer mirror 11 can be prepared by alternating layers, whose number falls within a range from not less than ten to several tens, of for example (i) TiO₂ (having a refractive index of approximately 2.3) employed as the first dielectric material and (ii) SiO₂ (having a refractive index of approximately 1.46) employed as the second dielectric material. Examples of the substrate encompass a glass substrate. Note, however, that Embodiment 1 is not limited to this, provided that the substrate has a light-transmitting property. The dielectric multilayer mirror 11 is provided on a surface of the substrate (second substrate).

According to Embodiment 1, the dielectric multilayer mirror 11 (i) reflects light which is a complementary color (i.e., purple) of a luminescent color (i.e., green) of the fluorescent molecules and (ii) causes light having the luminescent color (i.e., green) to pass through.

(Solar Cell 12)

The solar cell 12 is provided so that a light receiving surface of the solar cell 12 is adjacent to the end surface 2 of the fluorescent concentrating plate 10.

It is preferable that the solar cell 12 is selected in accordance with a luminescent color of a fluorescent concentrating plate 10 to be employed, while taking into consideration a factor such as sensibilities of various solar cell elements. In a case where, for example, the luminescent color of the fluorescent concentrating plate 10 is a luminescent color of light having a short wavelength, it is preferable to employ an amorphous silicon (α-Si) solar cell element. Alternatively, in a case where luminescent color of the fluorescent concentrating plate 10 is a luminescent color of light having a long wavelength, it is preferable to employ a polycrystalline silicon (p-Si) solar cell element. By selecting the solar cell 12 in this manner, it is possible to efficiently generate electric power. According to Embodiment 1, the fluorescent concentrating plate 10 emits green light, and therefore the following description will discuss a case where an a-Si solar cell element is employed as the solar cell 12.

The light receiving surface of the solar cell 12 is arranged to face the end surface 2 so that light emitted from the end surface 2 enters the solar cell 12. The solar cell 12 can be adhered to the end surface 2 with a gelling agent. In a case where the solar cell 12 is adhered to the end surface 2 with a gelling agent, it is possible to eliminate a difference in interfacial refractive index. This allows light, which has exited from the end surface 2 of the fluorescent concentrating plate 10, to efficiently enter the solar cell 12.

(Aluminum Frame 13)

The aluminum frame 13 is provided so as to surround peripheries of the fluorescent concentrating plate 10, the dielectric multilayer mirror 11, and the solar cell 12.

(Principle of Operation of Solar Power Generating Window 100)

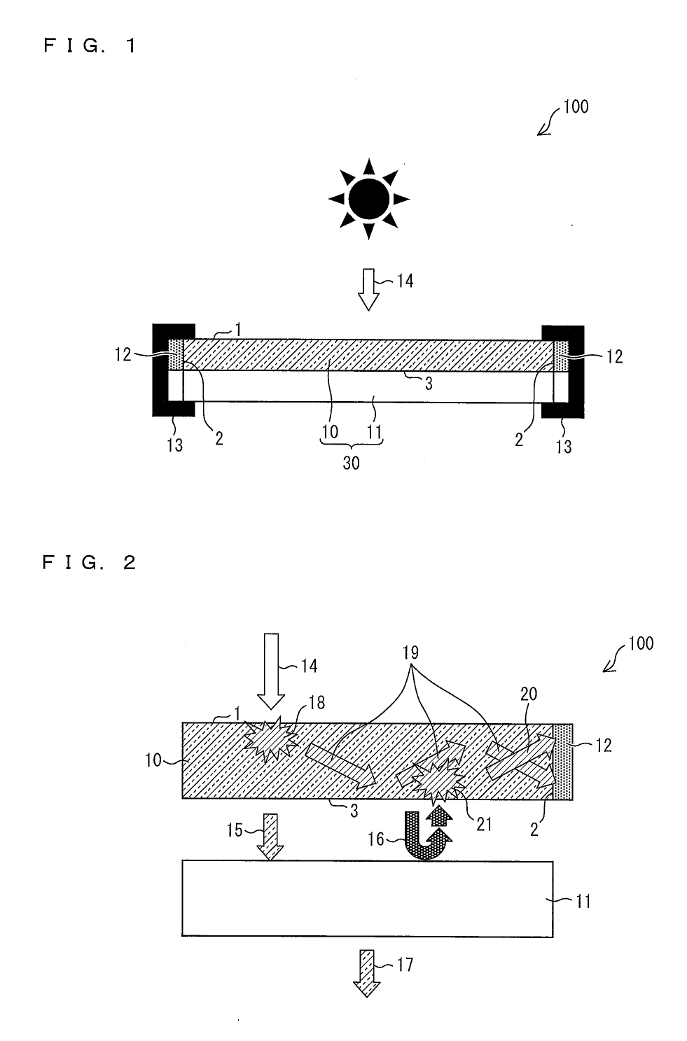

The following description will discuss a principle of how the solar power generating window 100 of Embodiment 1 operates, with reference to FIG. 2. FIG. 2 is a schematic view for illustrating how light is guided in the fluorescent concentrating plate 10 of the solar power generating window 100 in accordance with Embodiment 1.

Incoming light 14 enters the entrance surface 1 of the fluorescent concentrating plate 10. The fluorescent molecules contained in the fluorescent concentrating plate 10 are excited by purple light contained in entered light. The fluorescent molecules thus excited generate green fluorescence 18. The fluorescence 18, which is generated due to a part of the entered light, is guided toward the end surface 2 (first exit surface) of the fluorescent concentrating plate 10 along light paths 19 illustrated in FIG. 2, while being subjected to total reflection in the fluorescent concentrating plate 10. The fluorescence 18 thus guided to the end surface 2 exits from the end surface 2 and then enters the light receiving surface of the solar cell 12.

Outgoing light 15 exits from the exit surface 3 (second exit surface). The outgoing light 15 is (i) another part of the incoming light 14 which has entered the entrance surface 1, (ii) at least part of light other than the light that has exited from the end surface 2, and (iii) other than purple light absorbed by the fluorescent molecules. The outgoing light 15 enters the dielectric multilayer mirror 11. The dielectric multilayer mirror 11 causes green light to pass through (i.e., transmitted light 17) and reflects purple light (i.e., reflected light 16) having a complementary color of green. The reflected light 16 is purple light which has not been absorbed by the fluorescent molecules (i.e., which has not contributed to excitation of the fluorescent molecules). The reflected light 16, which is purple and has been thus reflected, reenters the fluorescent concentrating plate 10 and excites the fluorescent molecules so that fluorescence 21 is generated. The fluorescence 21 thus generated (i) is also guided toward the end surface 2 along a light path 20, while being subjected to total reflection in the fluorescent concentrating plate 10, and then (ii) enters the solar cell 12. The provision of the dielectric multilayer mirror 11 causes an increase in density of light which enters the solar cell 12. It is therefore possible to carry out solar power generation more efficiently.

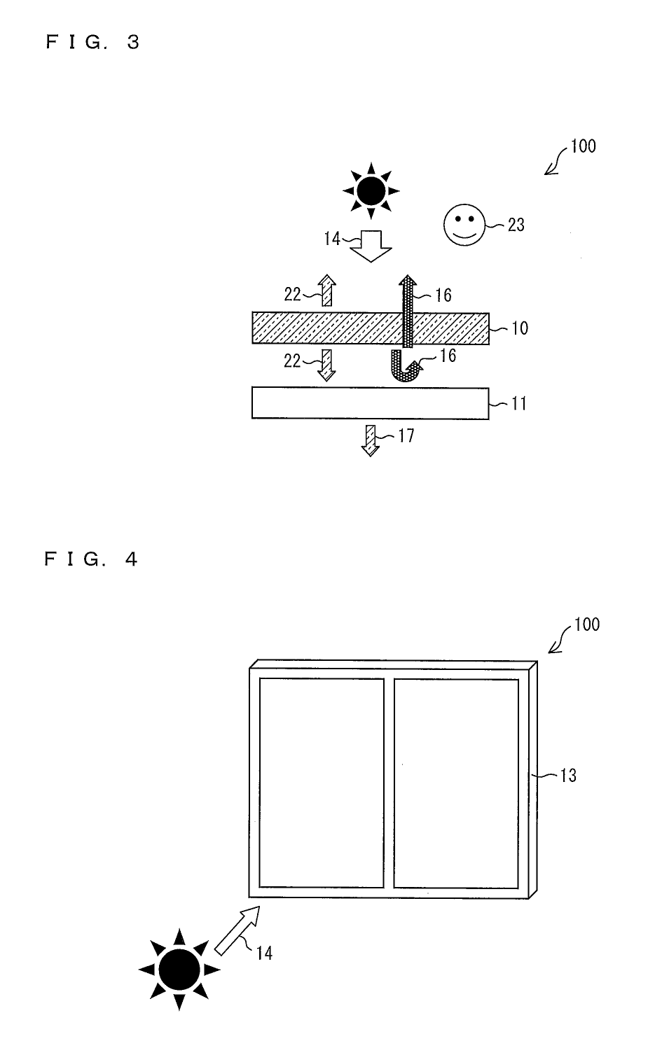

The following description will discuss, with reference to FIG. 3, a principle of how coloring of the solar power generating window 100 in accordance with Embodiment 1 is suppressed. In a case where the solar power generating window 100 is viewed by an outdoor viewer 23, the solar power generating window 100 looks achromatic. This is based on the fact that coloring of the solar power generating window 100 is suppressed (see FIG. 4) because (i) green fluorescence 22 which has been emitted from the fluorescent concentrating plate 10 and (ii) purple reflected light 16 which has been reflected from the dielectric multilayer mirror 11 and has passed through the fluorescent concentrating plate 10 again without contributing to excitation of the fluorescent molecules, are subjected to a color mixture on an outdoor viewer 23 side. Hereinafter, the “achromatic color” refers to a white, black, or gray color having a color saturation of zero. According to Embodiment 1, the solar power generating window 100 looks, for example, gray. It is therefore possible to suitably employ, as a window, the solar power generating window 100 without disfiguring a building having such a window.

In contrast, in a case where the solar power generating window 100 is viewed by an indoor viewer, the solar power generating window 100 looks green due to (i) the green fluorescence 22 emitted from the fluorescent concentrating plate 10 and (ii) green transmitted light 17 which has passed through the dielectric multilayer mirror 11.

According to Embodiment 1, the dielectric multilayer mirror 11 is thus provided on an indoor side of the fluorescent concentrating plate 10. The dielectric multilayer mirror 11 has a property causing (i) light, which has a first color of light emitted from the fluorescent concentrating plate 10, to pass through and (ii) light, having a second color which is a complementary color of the first color, to be reflected. With the configuration, coloring of a windowpane is suppressed, and therefore the windowpane looks achromatic for an outdoor viewer. This prevents (i) the outdoor viewer from feeling uncomfortable and (ii) a building from being disfigured. This allows a range of applications of the solar power generating window 100 not to be restricted. For example, it is possible to eliminate a case where a solar power generating window cannot be employed as a shop window because the solar power generating window is colored. Light, which has been reflected from the dielectric multilayer mirror 11, excites the fluorescent molecules in the fluorescent concentrating plate 10 so that fluorescence is generated. The fluorescence thus generated is also guided toward the end surface 2 and then enters the solar cell 12. This allows an increase in efficiency of solar power generation.

Note that an embodiment of the concentrating solar cell device of the present invention is obtained by removing the aluminum frame 13 from Embodiment 1.

### Embodiment 2

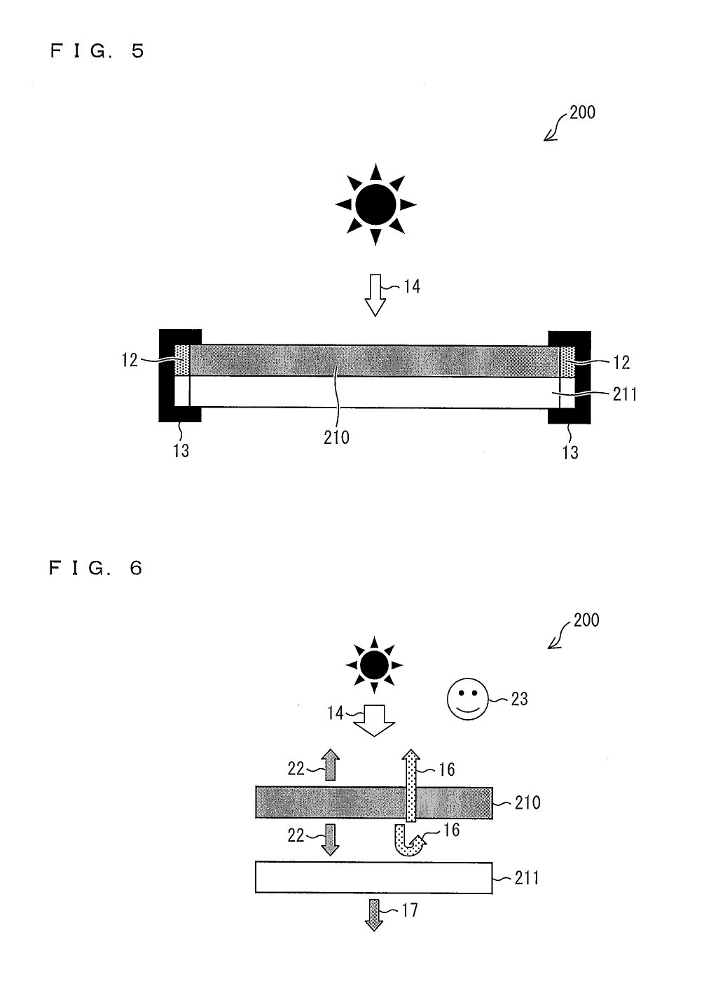

The following description will discuss Embodiment 2 of the present invention, with reference to FIGS. 5 and 6. Note that, for convenience, identical reference numerals are given to constituent members having functions identical with those of Embodiment 1, and descriptions of such constituent members are omitted. In Embodiment 2, differences from Embodiment 1 are mainly described.

FIG. 5 is a schematic view illustrating a configuration of a solar power generating window 200 in accordance with Embodiment 2. FIG. 6 is a schematic view for illustrating a principle of how coloring of the solar power generating window 200 in accordance with Embodiment 2 is suppressed.

The solar power generating window 200 has a configuration basically identical with that of the solar power generating window 100 (see FIG. 5). The solar power generating window 200 is different from the solar power generating window 100 in that the solar power generating window 200 includes, instead of the fluorescent concentrating plate 10, a fluorescent concentrating plate 210 containing fluorescent molecules that generate blue fluorescence. Examples of such fluorescent molecules encompass Lumogen F Blue 650 (manufactured by BASF). Note, however, that Embodiment 2 is not limited to this. According to Embodiment 2, the solar power generating window 200 includes, instead of the dielectric multilayer mirror 11, a dielectric multilayer mirror 211 which (i) causes blue light to pass through and (ii) reflects yellow light having a complementary color of blue.

In a case where the solar power generating window 200 is viewed by an outdoor viewer 23, the solar power generating window 200 looks achromatic. This is based on the fact that coloring of the solar power generating window 200 is suppressed (see FIG. 6) because (i) blue fluorescence 22 which has been emitted from the fluorescent concentrating plate 210 and (ii) yellow reflected light 16 which has been reflected from the dielectric multilayer mirror 211 and has passed through the fluorescent concentrating plate 10 again, are subjected to a color mixture on an outdoor viewer 23 side. The suppression of coloring allows the solar power generating window 200 to be suitably employed as a window, without disfiguring a building having such a window.

In a case where the solar power generating window 200 is viewed by an indoor viewer, the solar power generating window 200 looks blue due to (i) the blue fluorescence 22 emitted from the fluorescent concentrating plate 210 and (ii) blue transmitted light 17 which has passed through the dielectric multilayer mirror 211.

Embodiment 2 has discussed the case where the fluorescent molecules, which are contained in the fluorescent concentrating plate 210 and generate blue fluorescence, are not excited by yellow light. Therefore, the provision of the dielectric multilayer mirror 211 does not bring about an effect of improving efficiency of solar power generation.

### Embodiment 3

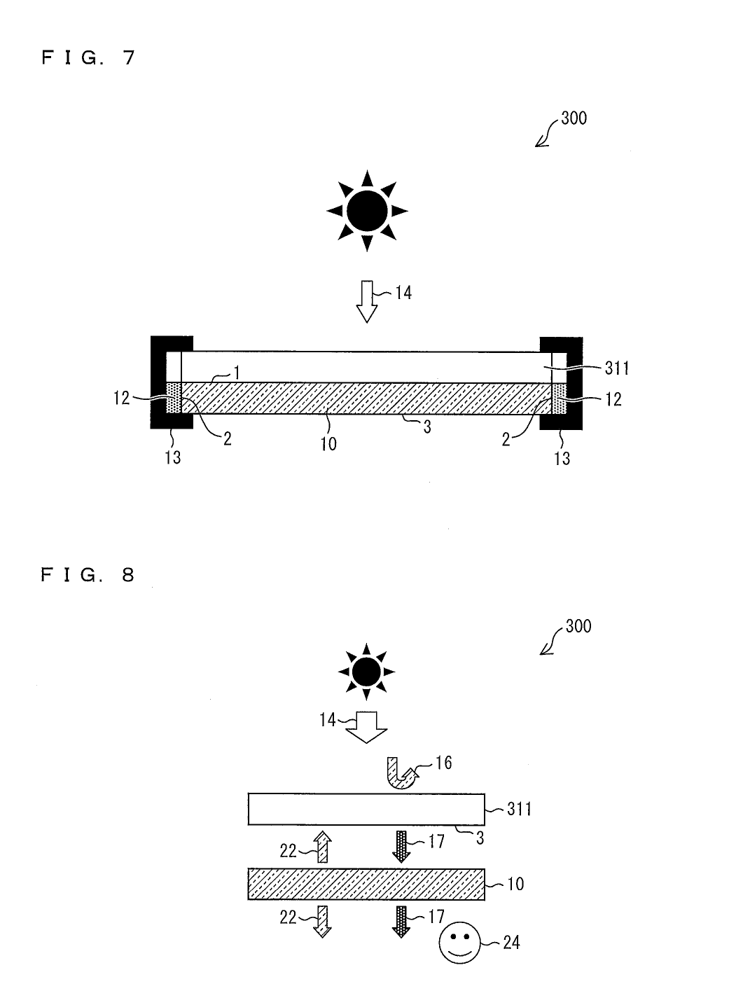

The following description will discuss Embodiment 3 of the present invention, with reference to FIGS. 7 and 8. Note that, for convenience, identical reference numerals are given to constituent members having functions identical with those of Embodiment 1, and descriptions of such constituent members are omitted. In Embodiment 3, differences from Embodiment 1 are mainly described.

FIG. 7 is a schematic view illustrating a configuration of a solar power generating window 300 in accordance with Embodiment 3. FIG. 8 is a schematic view for illustrating a principle of how coloring of the solar power generating window 300 in accordance with Embodiment 3 is suppressed.

The solar power generating window 300 is provided such that (i) a dielectric multilayer mirror 311 is located on an outdoor side which incoming light 14 enters and (ii) a fluorescent concentrating plate 10 is provided on an indoor side (see FIG. 7). The dielectric multilayer mirror 311 is stacked on the fluorescent concentrating plate 10 via an entrance surface 1 of the fluorescent concentrating plate 10.

According to Embodiment 3, the dielectric multilayer mirror 311 (i) reflects light which has a first color (i.e., green) of light generated by fluorescent molecules and (ii) causes light having a second color, which is a complementary color (i.e., purple) of the first color (i.e., green), to pass through.

The dielectric multilayer mirror 311 reflects green light (i.e., reflected light 16) contained in the incoming light 14 (see FIG. 8). The dielectric multilayer mirror 311 causes purple light to pass through (i.e., transmitted light 17) so that the purple light enters the fluorescent concentrating plate 10. The fluorescent concentrating plate 10 emits green fluorescence 22 in response to absorbed purple light.

In a case where the solar power generating window 300 is viewed by an indoor viewer 24, the solar power generating window 300 looks achromatic. This is based on the fact that coloring of the solar power generating window 300 is suppressed (see FIG. 8) because (i) green fluorescence 22 which has been emitted from the fluorescent concentrating plate 10 and (ii) purple transmitted light 17 which has passed through the fluorescent concentrating plate 10 (without contributing to excitation of the fluorescent molecules), are subjected to a color mixture on an indoor viewer 24 side. This makes it possible to suitably employ the solar power generating window 300 as a window, without spoiling a view from an indoor side.

In a case where the solar power generating window 300 is viewed by an outdoor viewer, the solar power generating window 300 looks green due to (i) the green fluorescence 22 emitted from the fluorescent concentrating plate 10 and (ii) the green transmitted light 17 which has been reflected from the dielectric multilayer mirror 311.

According to the configuration, a windowpane looks achromatic for an indoor viewer because coloring of the windowpane is suppressed. It is therefore possible to suitably employ, as a windowpane, the solar power generating window 300 without (i) making an indoor viewer uncomfortable and (ii) spoiling a view from an indoor side. Further, a range of applications of the solar power generating window 300 is not restricted due to coloring.

### Embodiment 4

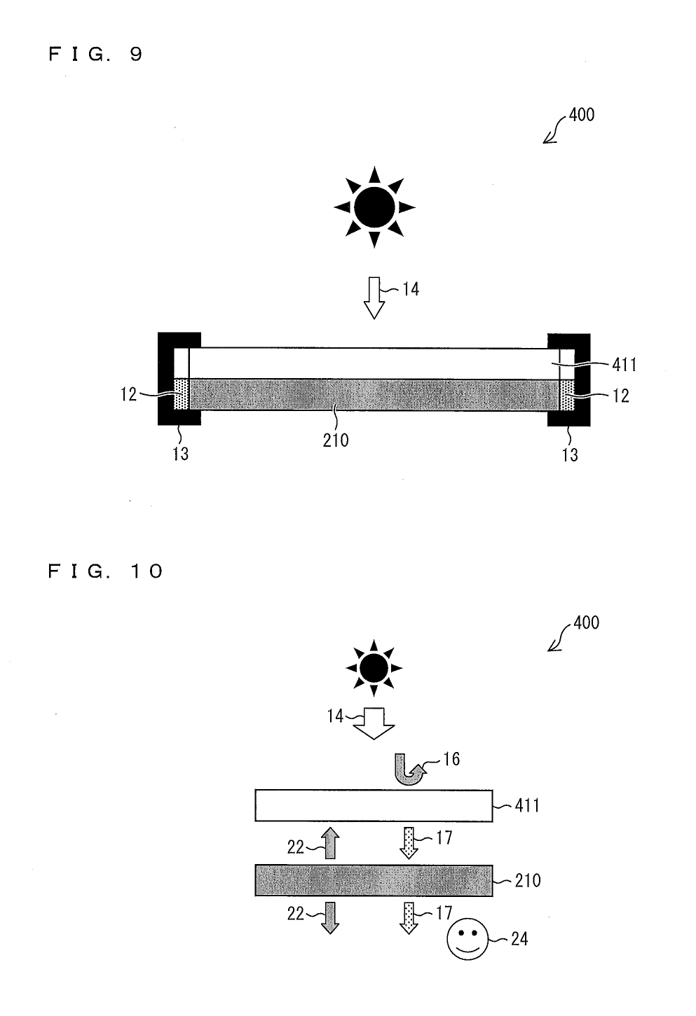

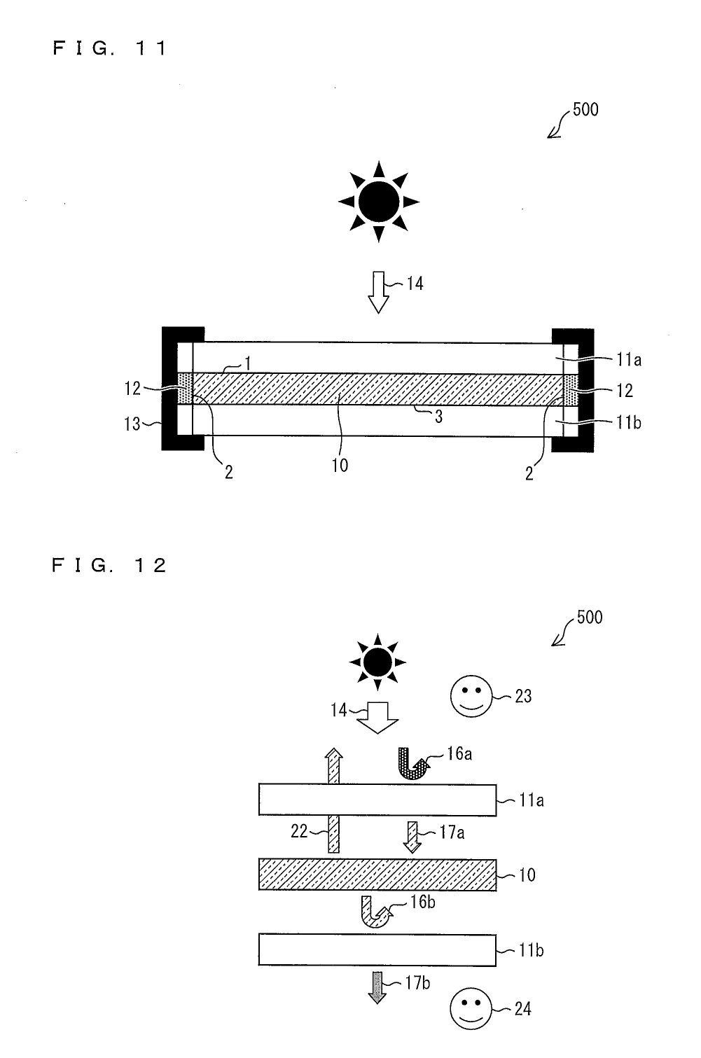

The following description will discuss Embodiment 4 of the present invention, with reference to FIGS. 9 and 10. Note that, for convenience, identical reference numerals are given to constituent members having functions identical with those of Embodiment 2, and descriptions of such constituent members are omitted. In Embodiment 4, differences from Embodiment 2 are mainly described. FIG. 9 is a schematic view illustrating a configuration of a solar power generating window 400 in accordance with Embodiment 4. FIG. 10 is a schematic view for illustrating a principle of how coloring of the solar power generating window 400 in accordance with Embodiment 4 is suppressed.

The solar power generating window 400 is provided such that (i) a dielectric multilayer mirror 411 is located on an outdoor side which incoming light 14 enters and (ii) a fluorescent concentrating plate 210 is provided on an indoor side (see FIG. 9). The dielectric multilayer mirror 411 is stacked on the fluorescent concentrating plate 210, via an entrance surface 1 of the fluorescent concentrating plate 210. According to Embodiment 4, the dielectric multilayer mirror 411 (i) reflects light which has a first color (i.e., blue) of light generated by fluorescent molecules and (ii) causes light having a second color, which is a complementary color (i.e., yellow) of the first color (i.e., blue), to pass through.

In a case where the solar power generating window 400 is viewed by an indoor viewer 24, the solar power generating window 400 looks achromatic. This is based on the fact that coloring of the solar power generating window 400 is suppressed (see FIG. 10) because (i) blue fluorescence 22 which has been emitted from the fluorescent concentrating plate 210 and (ii) yellow transmitted light 17 which has passed through the dielectric multilayer mirror 411 and the fluorescent concentrating plate 10, are subjected to a color mixture on an indoor viewer 24 side. This makes it possible to employ the solar power generating window 300 as a window, without spoiling a view from an indoor side.

In a case where the solar power generating window 400 is viewed by an outdoor viewer, the solar power generating window 400 looks blue due to (i) the blue fluorescence 22 emitted from the fluorescent concentrating plate 210 and (ii) blue reflected light 16 which has been reflected from the dielectric multilayer mirror 411.

According to the configuration, a windowpane looks achromatic for an indoor viewer because coloring of the windowpane is suppressed. It is therefore possible to prevent (i) an indoor viewer from feeling uncomfortable, (ii) a view from an indoor side from being spoiled, and (iii) a range of applications of the solar power generating window 400 from being restricted due to coloring.

### Embodiment 5

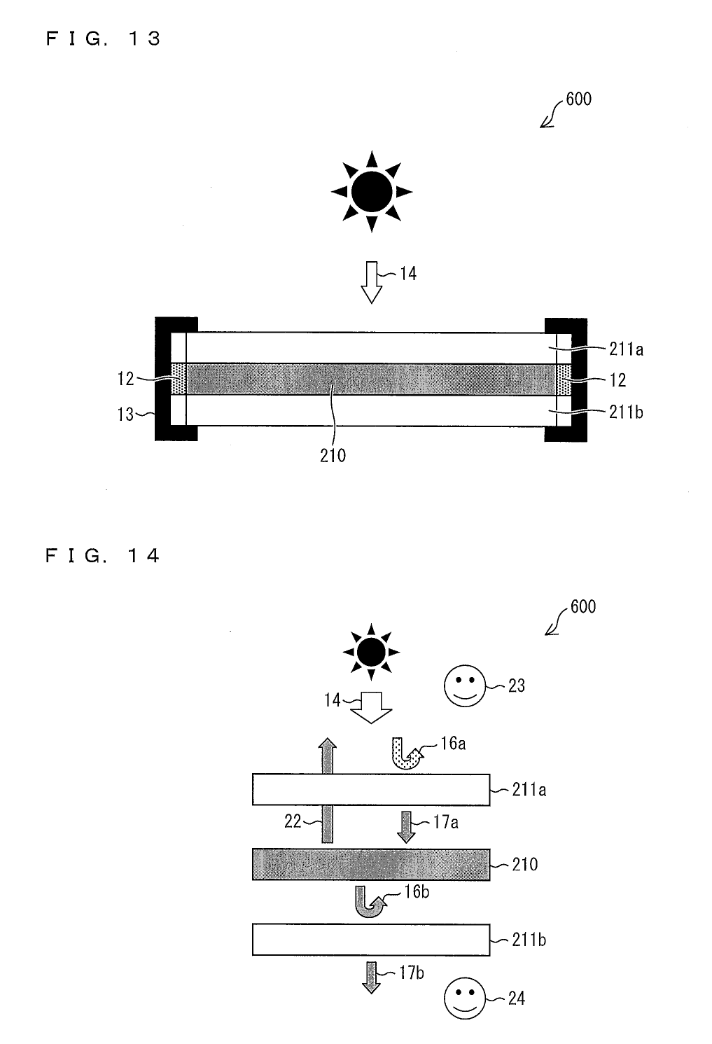

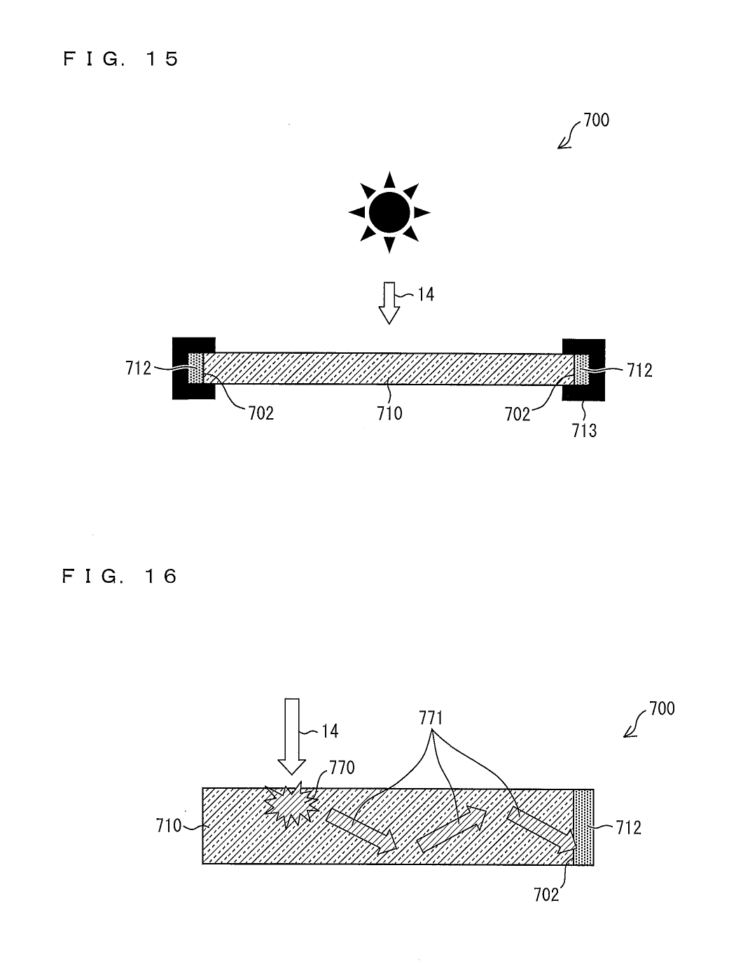

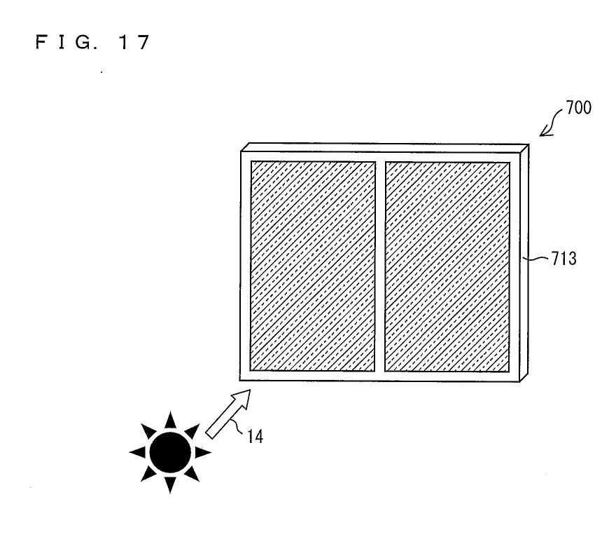

The following description will discuss Embodiment 5 of the present invention, with reference to FIGS. 11 and 12. Note that, for convenience, identical reference numerals are given to constituent members having functions identical with those of Embodiment 1, and descriptions of such constituent members are omitted. In Embodiment 5, differences from Embodiment 1 are mainly described.

FIG. 11 is a schematic view illustrating a configuration of a solar power generating window 500 in accordance with Embodiment 5. FIG. 12 is a schematic view for illustrating a principle of how coloring of the solar power generating window 500 in accordance with Embodiment 5 is suppressed.

According to the solar power generating window 500 of Embodiment 5, (i) a dielectric multilayer mirror 11a (second optical layer) is provided on an outdoor side of a fluorescent concentrating plate 10 and (ii) a dielectric multilayer mirror 11b (first optical layer) is provided on an indoor side of the fluorescent concentrating plate 10. The dielectric multilayer mirror 11a is stacked on the fluorescent concentrating plate 10 via an entrance surface 1 of the fluorescent concentrating plate 10. The dielectric multilayer mirror 11b is stacked on the fluorescent concentrating plate 10 via an exit surface of the fluorescent concentrating plate 10. According to Embodiment 5, the dielectric multilayer mirror 11a (i) reflects light having a second color, which is a complementary color (i.e., purple) of a first color (i.e., green) of light generated by fluorescent molecules and (ii) causes light having the first color (i.e., green) to pass through. The dielectric multilayer mirror 11b (i) reflects light having the first color (i.e., green) and (ii) causes light having the second color (i.e., purple) to pass through.

In a case where the solar power generating window 500 is viewed by an outdoor viewer 23, the solar power generating window 500 looks achromatic. This is based on the fact that coloring of the solar power generating window 500 is suppressed (see FIG. 12) because (i) green fluorescence 22 which has been emitted from the fluorescent concentrating plate 10 and (ii) purple reflected light 16a which has been reflected from the dielectric multilayer mirror 11a, are subjected to a color mixture on an outdoor viewer 23 side. In a case where the solar power generating window 500 is viewed by an indoor viewer 24, the solar power generating window 500 looks dim because green light, which has been emitted from the fluorescent concentrating plate 10, is mostly reflected by the dielectric multilayer mirror 11.

With the configuration of the solar power generating window 500, a windowpane looks hardly colored for both outdoor and indoor viewers. It is therefore possible to suitably employ, as a windowpane, the solar power generating window 500 without making outdoor and indoor viewers uncomfortable. Further, a range of applications of the solar power generating window 500 is not restricted due to coloring.

### Embodiment 6

The following description will discuss Embodiment 6 of the present invention, with reference to FIGS. 13 and 14. Note that, for convenience, identical reference numerals are given to constituent members having functions identical with those of Embodiment 5, and descriptions of such constituent members are omitted. In Embodiment 6, differences from Embodiment 5 are mainly described.

FIG. 13 is a schematic view illustrating a configuration of a solar power generating window 600 in accordance with Embodiment 6. FIG. 14 is a schematic view for illustrating a principle of how coloring of the solar power generating window 600 in accordance with Embodiment 6 is suppressed.

According to the solar power generating window 500 of Embodiment 6, (i) a dielectric multilayer mirror 211a is provided on an outdoor side of a fluorescent concentrating plate 210 and (ii) a dielectric multilayer mirror 211b is provided on an indoor side of the fluorescent concentrating plate 210. The fluorescent concentrating plate 210 contains fluorescent molecules that generate blue light. The dielectric multilayer mirror 211a (i) reflects light having a second color, which is a complementary color (i.e., yellow) of a first color (i.e., blue) of light generated by the fluorescent molecules and (ii) causes light having the first color (i.e., blue) to pass through. The dielectric multilayer mirror 211b (i) reflects light having the first color (i.e., blue) and (ii) causes light having the second color (i.e., yellow) to pass through.

In a case where the solar power generating window 600 is viewed by an outdoor viewer 23, the solar power generating window 600 looks achromatic. This is based on the fact that coloring of the solar power generating window 600 is suppressed (see FIG. 14) because (i) blue fluorescence 22 which has been emitted from the fluorescent concentrating plate 10 and (ii) yellow reflected light 16a which has been reflected from the dielectric multilayer mirror 211a, are subjected to a color mixture on an outdoor viewer 23 side. In a case where the solar power generating window 600 is viewed by an indoor viewer 24, the solar power generating window 600 looks dim because blue light, which has been emitted from the fluorescent concentrating plate 210, is mostly reflected by the dielectric multilayer mirror 211b.

With the configuration of the solar power generating window 600, a windowpane looks hardly colored for both outdoor and indoor viewers. It is therefore possible to suitably employ, as a windowpane, the solar power generating window 600 without making outdoor and indoor viewers uncomfortable. Further, a range of applications of the solar power generating window 600 is not restricted due to coloring.

<Additional Remarks>

According to the plate member of the present invention, it is preferable that the fluorescent layer is provided (i) inside a first substrate or (ii) on a surface of the first substrate; the optical layer is provided on a second substrate; and the first substrate and the second substrate are stacked.

According to the configuration, the fluorescent layer and the optical layer are provided on respective two substrates, and the plate member is configured by stacking the two substrates. This allows the substrate having the optical layer to be arranged on an indoor side, on an outdoor side, or on both sides of the fluorescent layer. This makes it possible to provide the plate member that can be used as a windowpane, whose coloring is suppressed by adjusting its mounted location, even in a case where the windowpane is viewed by an outdoor viewer, an indoor viewer, or both the viewers.

According to the plate member of the present invention, it is possible that the fluorescent layer and the optical layer are stacked such that light, which (i) has the complementary color and (ii) has been reflected from or has passed through the optical layer, enters the fluorescent layer.

According to the configuration, the light, which has the complementary color of the color of light generated by the fluorescent molecules, enters the fluorescent layer. With the configuration, in a case where the plate member is viewed from a side opposite to a side on which the optical layer is provided, coloring is suppressed because the color of light emitted from the fluorescent layer is mixed with light which (i) has passed through or has been reflected from the optical layer and (ii) has the complementary color.

According to the plate member of the present invention, it is possible that the optical layer (i) reflects the light having the complementary color of the color of the light generated by the fluorescent molecules and (ii) causes the light, having the color of the light generated by the fluorescent molecules, to pass through; the light entrance surface and the second exit surface serve as a front surface and a back surface, respectively, of the fluorescent layer; and the optical layer is stacked on a second exit surface side of the fluorescent layer.

According to the configuration, the light having the complementary color of the color of the light generated by the fluorescent molecules is reflected by the optical layer and reenters the fluorescent layer. With the configuration, in a case where the plate member is viewed from a side opposite to a side on which the optical layer is provided, coloring is suppressed because the color of light emitted from the fluorescent layer is mixed with light which has been reflected from the optical layer and has the complementary color.

According to the plate member of the present invention, it is possible that the optical layer (i) causes the light, having the complementary color of the color of the light generated by the fluorescent molecules, to pass through and (ii) reflects the light having the color of the light generated by the fluorescent molecules; the light entrance surface and the second exit surface serve as a front surface and a back surface, respectively, of the fluorescent layer; and the optical layer is stacked on a light entrance surface side of the fluorescent layer.

According to the configuration, the optical layer causes the light, having the complementary color of the color of the light generated by the fluorescent molecules, to pass through. With the configuration, in a case where the plate member is viewed from a side opposite to a side on which the fluorescent layer is provided, coloring is suppressed because the color of light emitted from the fluorescent layer is mixed with light which has passed through the optical layer and has the complementary color.

According to the plate member of the present invention, it is possible that the optical layer is a first optical layer and a second optical layer; the first optical layer (i) causes the light, having the complementary color of the color of the light generated by the fluorescent molecules, to pass through and (ii) reflects the light having the color of the light generated by the fluorescent molecules; the second optical layer (i) reflects the light having the complementary color of the color of the light generated by the fluorescent molecules and (ii) causes the light having the color of the light generated by the fluorescent molecules to pass through; the light entrance surface and the second exit surface serve as a front surface and a back surface, respectively, of the fluorescent layer; the first optical layer is stacked on a second exit surface side of the fluorescent layer; and the second optical layer is stacked on a light entrance surface side of the fluorescent layer.

According to the configuration, in a case where the plate member is viewed from a side of the fluorescent layer on which side the second optical layer is provided, coloring is suppressed because light, which has been reflected from the second optical layer and has the complementary color, is mixed with the light emitted from the fluorescent layer. Moreover, in a case where the plate member is viewed from a side of the fluorescent layer on which side the first optical layer is provided, coloring is suppressed because the light emitted from the fluorescent layer is mostly reflected by the first optical layer.

According to the concentrating solar cell device of the present invention, it is possible that the solar cell is adhered to the first exit surface with a gelling agent.

According to the configuration, it is possible to eliminate a difference in interfacial refractive index. This allows light, which has exited from the first exit surface of the fluorescent concentrating plate, to efficiently enter the solar cell.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The plate member, the solar cell device, and the solar power generating window of the present invention (i) can be suitably applied to a window of a building and (ii) can carry out highly efficient solar power generation.

### REFERENCE SIGNS LIST

1: Entrance surface
2: End surface (first exit surface)
3: Exit surface (second exit surface)
10, 210: Fluorescent concentrating plate (fluorescent layer)
11, 11a, 11b, 211, 211a, 211b, 311, 411: Dielectric multilayer mirror (optical layer)
12: Solar cell
13: Aluminum frame
14: Incoming light
15: Outgoing light
16: Reflected light
17: Transmitted light
18, 21, 22: Fluorescence
19, 20: Light path
23, 24: Viewer
30: Plate member
100, 200, 300, 400, 500, 600: Solar power generating window

1. A plate member having:
a light entrance surface;
a first exit surface from which first light exits, the first light (i) being a part of entered light which has entered the light entrance surface and (ii) having been guided toward the first exit surface; and
a second exit surface from which second light exits, the second light being at least part of rest of the entered light,
said plate member comprising:
a fluorescent layer containing fluorescent molecules; and
an optical layer,
the optical layer (i) reflecting light having a complementary color of a color of light generated by the fluorescent molecules or (ii) causing the light, having the complementary color of the color of the light generated by the fluorescent molecules, to pass through, and
the fluorescent layer and the optical layer being stacked.

2. The plate member as set forth in claim 1, wherein:
the fluorescent layer is provided (i) inside a first substrate or (ii) on a surface of the first substrate;
the optical layer is provided on a second substrate; and
the first substrate and the second substrate are stacked.

3. The plate member as set forth in claim 1, wherein:
the fluorescent layer and the optical layer are stacked such that light, which (i) has the complementary color and (ii) has been reflected from or has passed through the optical layer, enters the fluorescent layer.

4. The plate member as set forth in claim 1, wherein:
the optical layer (i) reflects the light having the complementary color of the color of the light generated by the fluorescent molecules and (ii) causes the light, having the color of the light generated by the fluorescent molecules, to pass through;
the light entrance surface and the second exit surface serve as a front surface and a back surface, respectively, of the fluorescent layer; and
the optical layer is stacked on a second exit surface side of the fluorescent layer.

5. The plate member as set forth in claim 1, wherein:
the optical layer (i) causes the light, having the complementary color of the color of the light generated by the fluorescent molecules, to pass through and (ii) reflects the light having the color of the light generated by the fluorescent molecules;
the light entrance surface and the second exit surface serve as a front surface and a back surface, respectively, of the fluorescent layer; and
the optical layer is stacked on a light entrance surface side of the fluorescent layer.

6. The plate member as set forth in claim 1, wherein:
the optical layer is a first optical layer and a second optical layer;
the first optical layer (i) causes the light, having the complementary color of the color of the light generated by the fluorescent molecules, to pass through and (ii) reflects the light having the color of the light generated by the fluorescent molecules;
the second optical layer (i) reflects the light having the complementary color of the color of the light generated by the fluorescent molecules and (ii) causes the light having the color of the light generated by the fluorescent molecules to pass through;
the light entrance surface and the second exit surface serve as a front surface and a back surface, respectively, of the fluorescent layer;
the first optical layer is stacked on a second exit surface side of the fluorescent layer; and
the second optical layer is stacked on a light entrance surface side of the fluorescent layer.

7. A concentrating solar cell device comprising:
a plate member recited in claim 1; and
a solar cell,
the first exit surface facing a light receiving surface of the solar cell so that light, which has exited from the first exit surface, enters the solar cell.

8. The concentrating solar cell device as set forth in claim 7, wherein:
the solar cell is adhered to the first exit surface with a gelling agent.

9. A solar power generating window comprising a concentrating solar cell device recited in claim 7.
